(19) United States
(12) Patent Application Publication
(10) Pub. No.: US 2026/0231644 A1
(43) Pub. Date: Aug. 6, 2026

(54) DISPLAY DEVICE, METHOD OF PROVIDING DISPLAY DEVICE, AND ELECTRONIC APPARATUS INCLUDING DISPLAY DEVICE

(71) Applicant: Samsung Display Co., Ltd., Yongin-si (KR)

(72) Inventors: Euna Yang, Yongin-si (KR); Hansu Kim, Yongin-si (KR)

(21) Appl. No.: 19/375,431

(22) Filed: Oct. 31, 2025

(30) Foreign Application Priority Data
Feb. 6, 2025 (KR) 10-2025-0015332

(51) Int. Cl. H10K 59/38; H10K 59/12; H10K 59/122; H10K 59/80; H10K 102/00

(52) U.S. Cl. CPC H10K 59/38; H10K 59/1201; H10K 59/122; H10K 59/873; H10K 59/877; H10K 59/8792; H10K 2102/351

(57) ABSTRACT

A display device includes a bank layer in which openings are defined respectively defining a first emission area and a second emission area, a first light-emitting element and a second light-emitting element in the first emission area and in the second emission area, respectively, an organic encapsulation layer on the bank layer, a color filter layer on the organic encapsulation layer, the color filter layer including a first color filter overlapping the first light-emitting element and a second color filter overlapping the second light-emitting element, the first color filter spaced apart from the second color filter with a gap therebetween, and an overcoat layer covering the first color filter and the second color filter and extended into the gap between the first color filter and the second color filter.

This application claims priority to Korean Patent Application No. 10-2025-0015332, filed on February 6, 2025, and all the benefits accruing therefrom under 35 U.S.C. §119, the disclosure of which is incorporated by reference herein in its entirety.

### BACKGROUND

### 1. Field

One or more embodiments relate to a display device, a method of manufacturing (or providing) the display device, and an electronic apparatus including the display device. More particularly, one or mor embodiments related to a display device with improved light output efficiency, a method of manufacturing (or providing) the display device, and an electronic apparatus including the display device.

### 2. Description of the Related Art

Electronic apparatuses have been widely used. Electronic apparatuses are used in various ways, such as mobile electronic apparatuses and stationary electronic apparatuses. Such electronic apparatuses include display devices to provide visual information, such as images or videos, to users so as to support various functions of the electronic apparatuses.

A display device includes a plurality of pixels configured to receive electrical signals and emit light so as to display images visible from an outside of the display device. Each of the pixels includes a light-emitting element. For example, an organic light-emitting display device includes an organic light-emitting diode as a light-emitting element. In general, an organic light-emitting display device includes a thin-film transistor and an organic light-emitting diode on a substrate. The organic light-emitting diode operates to itself emit light.

### SUMMARY

As the usage of display devices has diversified, various attempts have been made to improve the quality of display devices.

One or more embodiments include a display device with improved process efficiency, a method of manufacturing the display device, and an electronic apparatus including the display device.

However, such an objective is only an example, and the objectives to be achieved by the disclosure are not limited thereto.

Additional aspects will be set forth in part in the description which follows and, in part, will be apparent from the description, or may be learned by practice of the presented embodiments of the disclosure.

According to one or more embodiments, a display device includes a substrate, a first light-emitting element and a second light-emitting element on the substrate, a bank layer having openings respectively corresponding to the first light-emitting element and the second light-emitting element so as to define a first emission area and a second emission area, an organic encapsulation layer disposed on the bank layer, a first color filter disposed on the organic encapsulation layer to overlap the first emission area and a second color filter disposed on the organic encapsulation layer to overlap the second emission area, and an overcoat layer covering the first color filter and the second color filter and filling a gap between the first color filter and the second color filter.

In an embodiment, a surface of the organic encapsulation layer may be hydrophobically coated.

In an embodiment, the first color filter and the second color filter may each have a convex hemispherical dome shape.

In an embodiment, the display device may further include a first encapsulation member disposed between the organic encapsulation layer and the first color filter and a second encapsulation member disposed between the organic encapsulation layer and the second color filter, where the first encapsulation member and the second encapsulation member may be spaced apart from each other.

In an embodiment, the display device may further include a first scattering portion disposed on the first encapsulation member and a second scattering portion disposed on the second encapsulation member.

In an embodiment, in a plan view, the first color filter may cover the first encapsulation member and the first scattering portion so that the first encapsulation member and the first scattering portion are disposed within a periphery of the first color filter.

In an embodiment, the display device may further include a light-blocking portion disposed between the first color filter and the second color filter, where the light-blocking portion may be spaced apart from the first color filter and the second color filter.

In an embodiment, the light-blocking portion may include a first portion having a same material as a material of the first color filter and a second portion having a same material as a material of the second color filter.

In an embodiment, the second portion may be disposed to surround the first portion.

In an embodiment, the light-blocking portion may include a black material.

According to one or more embodiments, a method of manufacturing a display device includes disposing a light-emitting element on a substrate, disposing, on the light-emitting element, a bank layer having an opening corresponding to the light-emitting element so as to define an emission area, disposing an organic encapsulation layer on the bank layer, patterning an inorganic encapsulation layer and a scattering layer in a portion overlapping the emission area on the organic encapsulation layer, and forming a color filter by jetting ink to cover the inorganic encapsulation layer and the scattering layer.

In an embodiment, the method may further include hydrophobically coating a surface of the organic encapsulation layer.

In an embodiment, the forming of the color filter may include jetting ink so that the color filter has a convex hemispherical shape.

In an embodiment, the forming of the color filter may include covering the inorganic encapsulation layer and the scattering layer so that the inorganic encapsulation layer and the scattering layer are disposed within a periphery of the color filter in a plan view.

In an embodiment, the method may further include disposing a light-blocking portion along a periphery of the color filter in a plan view.

In an embodiment, the light-blocking portion may be spaced apart from the periphery of the color filter.

In an embodiment, the light-blocking portion may include a same material as a material of the color filter.

In an embodiment, the disposing of the light-blocking portion may include jetting ink.

In an embodiment, the light-blocking portion may include a black material.

According to one or more embodiments, an electronic apparatus includes a processor and a display device configured to be controlled by the processor, where the display device includes a substrate, a first light-emitting element and a second light-emitting element on the substrate, a bank layer having openings respectively corresponding to the first light-emitting element and the second light-emitting element so as to define a first emission area and a second emission area, an organic encapsulation layer disposed on the bank layer, a first color filter disposed on the organic encapsulation layer to overlap the first emission area and a second color filter disposed on the organic encapsulation layer to overlap the second emission area, and an overcoat layer covering the first color filter and the second color filter and filling a gap between the first color filter and the second color filter.

Other aspects, features, and advantages of the disclosure will become apparent from the following detailed description, the claims, and the drawings for carrying out the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic block diagram of an electronic apparatus according to an embodiment;

FIG. 2 is a schematic diagram of electronic apparatuses according to embodiments;

FIG. 3 is a schematic perspective view of a display device according to an embodiment;

FIG. 4 illustrates a light-emitting element and a pixel circuit connected thereto, which are provided in a pixel of a display device according to an embodiment;

FIG. 5 is a schematic cross-sectional view of the display device of FIG. 3 taken along line IV-IV’ of FIG. 3, according to an embodiment;

FIG. 6 is a schematic cross-sectional view of a display device according to an embodiment;

FIGS. 7 and 8 are schematic cross-sectional views of a display device according to an embodiment; and

FIGS. 9 to 11 schematically illustrate a method of manufacturing a display device, according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

In the following embodiments, the terms "first," "second," etc. are not used in a restrictive sense and are used to distinguish one element from another.

The singular forms as used herein are intended to include the plural forms as well unless the context clearly indicates otherwise.

It will be understood that the terms "include" and/or "comprise" used herein specify the presence of stated features or elements, but do not preclude the presence or addition of one or more other features or elements.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be further understood that, when a layer, region, or element is referred to as being related to another element such as being "on" another layer, region, or element, it may be directly on the other layer, region, or element, but also intervening layers, regions, or elements may be present therebetween. In contrast, when a layer, region, or element is referred to as being related to another element such as being "directly on" another layer, region, or element, no intervening layer, region or element is present therebetween. As being in “contact,” elements may form a physical interface therebetween.

It will be understood that when layers, regions, or elements are referred to as being connected to each other, they may be directly connected to each other or indirectly connected to each other with intervening layers, regions, or elements therebetween. In addition, when layers, regions, or elements are referred to as being electrically connected to each other, they may be directly electrically connected to each other or indirectly electrically connected to each other with intervening layers, regions, or elements therebetween.

Also, sizes of elements in the drawings may be exaggerated or reduced for convenience of explanation. For example, since sizes and thicknesses of elements in the drawings are arbitrarily illustrated for convenience of explanation, the disclosure is not necessarily limited thereto.

As used herein, the expression "A and/or B" indicates only A, only B, or both A and B. The expression "at least one of A and B" indicates only A, only B, or both A and B.

In the following embodiments, the expression "a wiring extends in a first direction or a second direction" means that the wiring extends in a straight-line shape, and also means that the wiring extends in a zigzag or curved shape along the first direction or the second direction.

In the following embodiments, the term "in a plan view" as used herein means seeing a target portion from above. In the following embodiments, the term “in a cross-sectional view” as used herein means seeing a vertically cut cross-section of a target portion from the side. In the following embodiments, when a first element "overlaps" a second element, it means that the first element is disposed above or below the second element.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When a certain embodiment is implemented differently, a specific process sequence may be performed differently from a sequence described herein. For example, two consecutively described processes may be performed substantially at the same time or performed in an order opposite to the stated order.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

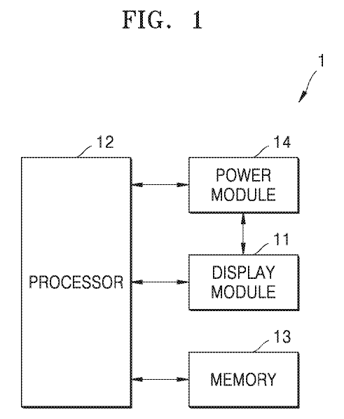

FIG. 1 is a schematic block diagram of an electronic apparatus 1 according to an embodiment. The electronic apparatus 1 according to an embodiment may include a display module 11 and may further include modules which have additional functions. For example, as illustrated in FIG. 1, the electronic apparatus 1 according to an embodiment may include the display module 11, a processor 12, a memory 13, and a power module 14.

The processor 12 may be configured to control the elements of the electronic apparatus 1. The processor 12 may include at least one of a central processing unit (CPU), an application processor (AP), a graphics processing unit (GPU), a communication processor (CP), an image signal processor (ISP) and a controller.

The memory 13 may be configured to store data information necessary for the operation of the processor 12 or the display module 11. When the processor 12 executes an application stored in the memory 13, an image data signal and/or an input control signal may be transmitted to the display module 11, and the display module 11 may process the received signal and output image information.

The power module 14 may include a power supply module, such as a power adapter or a battery device, and a power conversion module configured to convert power supplied by the power supply module to generate power necessary for the operation of the electronic apparatus 1.

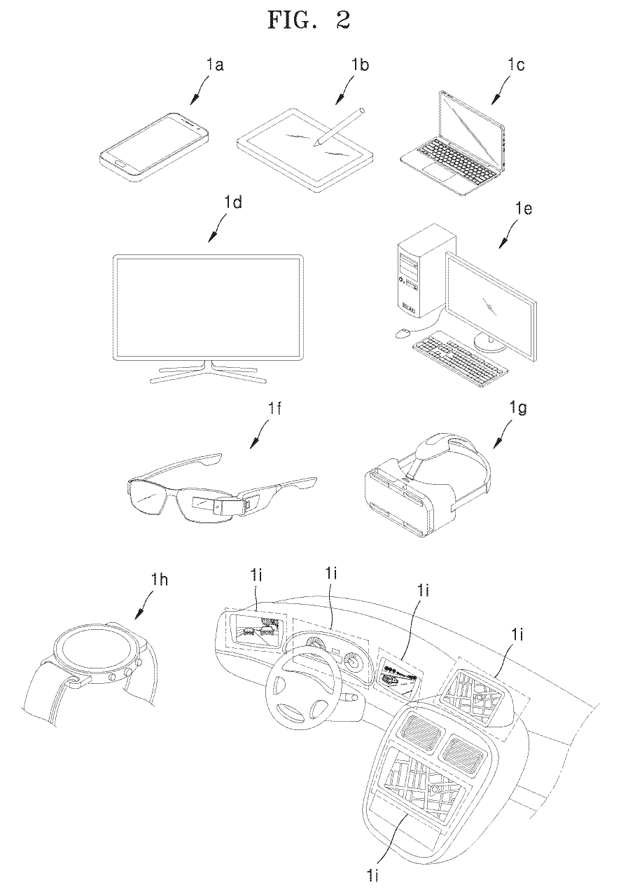

FIG. 2 is a schematic diagram of electronic apparatuses 1 according to embodiments. Referring to FIG. 2, the electronic apparatuses 1 each including the display module 11 may include electronic apparatuses for image display, such as a smartphone 1a, a tablet personal computer (PC) 1b, a laptop 1c, a television (TV) 1d, or a desk monitor 1e, wearable electronic apparatuses each including the display module 11, such as smart glasses 1f, a head mounted display 1g, or a smart watch 1h, and vehicle electronic apparatuses 1i each including the display module 11, such as dashboards of automobiles, center information displays (CIDs) on the center fascia or dashboards of automobiles, or room mirror displays.

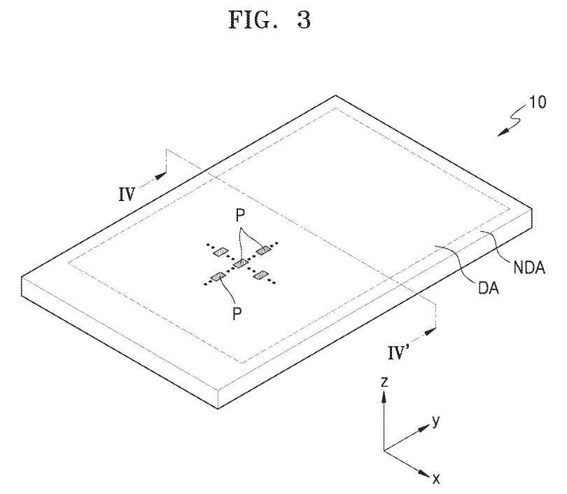

The display module 11 may include a display device (see 10 of FIG. 3). The display device 10 may be applied to various electronic apparatuses 1. That is, the electronic apparatus 1 may include the display device 10 and may further include modules or devices having additional functions other than the display device 10. For example, the electronic apparatus 1 may include the display device 10, the processor 12, the memory 13 and the power module 14, and the display device 10 may be controlled by the processor 12. Hereinafter, the display device 10 is mainly described.

FIG. 3 is a schematic perspective view of a display device 10 according to an embodiment.

Referring to FIG. 3, the display device 10 may include a display area DA and a peripheral area NDA which is adjacent to the display area DA such as being outside the display area DA. The display device 10 may be configured to provide an image through an array of a plurality of pixels P two-dimensionally disposed in the display area DA. That is, a pixel P may be provided in plural including pixels P in the display area DA. Within the Figures and the text of the disclosure, a reference number indicating a singular form of an element may also be used to reference a plurality of the element.

The pixels P of the display device 10 are areas (e.g., planar areas) in which pieces of light of certain colors are emitted, and the display device 10 may be configured to provide images by using the pieces of light emitted from the pixels P. For example, each of the pixels P may be configured to emit red light, green light, blue light, or white light.

Each of the pixels P may be configured to emit light of a certain color by using a light-emitting element, for example, an organic light-emitting diode. The organic light-emitting diode may be configured to emit, for example, red light, green light, blue light, or white light. The organic light-emitting diode may be connected to a pixel circuit including a thin-film transistor and a capacitor.

The peripheral area NDA is an area (e.g., a planar area) in which an image is not provided, such as to define a non-display area adjacent to the display area DA. The peripheral area NDA may completely surround the display area DA in a plan view. A driver or a main power line configured to provide electrical signals or power to pixel circuits may be disposed in the peripheral area NDA. A pad, which is an area or element at which an electronic element or a printed circuit board is electrically connectable, may be disposed in the peripheral area NDA.

The display area DA may have a polygonal shape, including a rectangular shape, as illustrated in FIG. 3. For example, among planar shapes, the display area DA may have a rectangular shape in which a horizontal length is greater than a vertical length, a rectangular shape in which a horizontal length is less than a vertical length, or a square shape. Alternatively, the display area DA may have other planar shapes, such as an elliptical shape or a circular shape.

The display device 10 may be used in electronic apparatuses, such as mobile phones, TVs, billboards, tablet PCs, laptops, and smart watches or smart bands worn on the wrist.

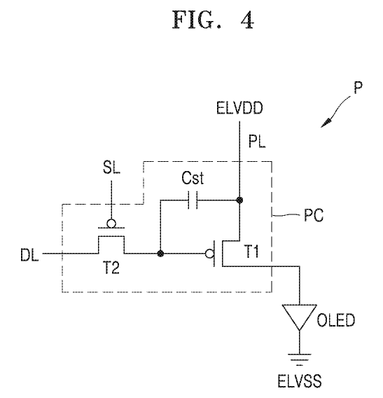

FIG. 4 illustrates a light-emitting element and a pixel circuit connected thereto, which are provided in a pixel P of a display device 10 according to an embodiment.

Referring to FIG. 4, as a light-emitting element, an organic light-emitting diode OLED may be connected to a pixel circuit PC. The pixel circuit PC may include a first thin-film transistor T1, a second thin-film transistor T2, and a storage capacitor Cst.

The second thin-film transistor T2, which acts as a switching thin-film transistor, may be connected to a scan line SL and a data line DL as signal lines. The second thin-film transistor T2 may be configured to transmit, to the first thin-film transistor T1, a data voltage input from the data line DL in response to a switching voltage input from the scan line SL. The storage capacitor Cst may be connected (e.g., physically and/or electrically connected) to the second thin-film transistor T2 and a driving voltage line PL and may be configured to store a voltage corresponding to the difference between a voltage received from the second thin-film transistor T2 and a driving voltage ELVDD supplied to the driving voltage line PL.

The first thin-film transistor T1, which acts as a driving thin-film transistor, may be connected to the driving voltage line PL and the storage capacitor Cst and may be configured to control a driving current (e.g., electrical current) flowing from the driving voltage line PL to the organic light-emitting diode OLED according to a voltage value stored in the storage capacitor Cst.

The organic light-emitting diode OLED may be configured to emit light with a certain luminance according to the driving current. The organic light-emitting diode OLED may be connected to the pixel circuit PC at a pixel electrode (e.g., an anode) of the organic light-emitting diode OLED. An opposite electrode (e.g., a cathode) of the organic light-emitting diode OLED may be configured to receive a common voltage ELVSS.

FIG. 4 illustrates that the pixel circuit PC includes two thin-film transistors and one storage capacitor, but is not limited thereto. In embodiments, the number of thin-film transistors or the number of storage capacitors may be variously changed according to the design of the pixel circuit PC.

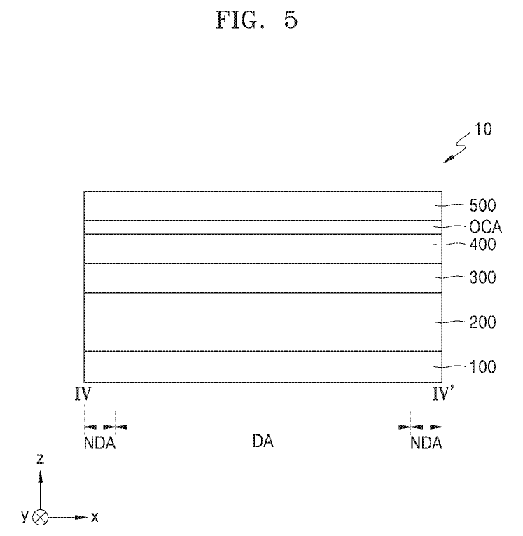

FIG. 5 is a schematic cross-sectional view of the display device 10 of FIG. 3 taken along line IV-IV’ of FIG. 3, according to an embodiment. Referring to FIGS. 3 and 5, the display device 10 may be disposed in a plane (e.g., an XY plane) defined by a first direction (like the X-axis) crossing a second direction (like the Y-axis). A planar direction may be defined along the plane. A thickness of the display device 10 or various components or layers thereof may be defined along a third direction (like the Z-axis). A thickness direction or a plan view may be taken along the third direction. The various directions may be perpendicular to each other, without being limited thereto.

Referring to FIG. 5, the display device 10 may include a substrate 100, a display layer 200, an encapsulation layer 300, an anti-reflection layer 400, an adhesive layer OCA, and a cover window 500.

The substrate 100 may include glass or polymer resin. For example, the polymer resin may include polyethersulfone, polyacrylate, polyether imide, polyethylene naphthalate, polyethylene terephthalate, polyphenylene sulfide, polyarylate, polyimide, polycarbonate, or cellulose acetate propionate. The substrate 100 including the polymer resin may be flexible, rollable, or bendable, such that the display device 10 is flexible, rollable, or bendable at one or more regions along a planar direction of the substrate 10. The substrate 100 may have a multilayer structure including a polymer resin-containing layer (not shown) and an inorganic layer (not shown).

The display layer 200 may include thin-film transistors electrically connected to light-emitting elements, for example, organic light-emitting diodes, and insulating layers therebetween. That is, the display layer 200 may include a light-emitting element layer electrically connected to a pixel circuit layer.

The encapsulation layer 300 may be disposed on the display layer 200. For example, the display layer 200 may be sealed by the encapsulation layer 300. The encapsulation layer 300 may include at least one inorganic encapsulation layer and at least one organic encapsulation layer.

The anti-reflection layer 400 may be disposed on the encapsulation layer 300. The anti-reflection layer 400 may reduce the reflectance of external light incident from the outside toward the display device 10 through the cover window 500.

The anti-reflection layer 400 may include color filters and an overcoat layer. The color filters may be disposed by taking into account the color of light emitted from each of the light-emitting elements of the display layer 200. The overcoat layer may be disposed to cover the color filters.

The cover window 500 may be disposed on the anti-reflection layer 400, for example, the overcoat layer. The cover window 500 may protect layers disposed under the cover window 500, such as the display layer 200. The cover window 500 may be formed (or provided) separately and then attached to the anti-reflection layer 400 by the adhesive layer OCA disposed between the cover window 500 and the anti-reflection layer 400. The adhesive layer OCA may be, for example, an optically clear adhesive. Alternatively, the cover window 500 may be directly formed on the anti-reflection layer 400.

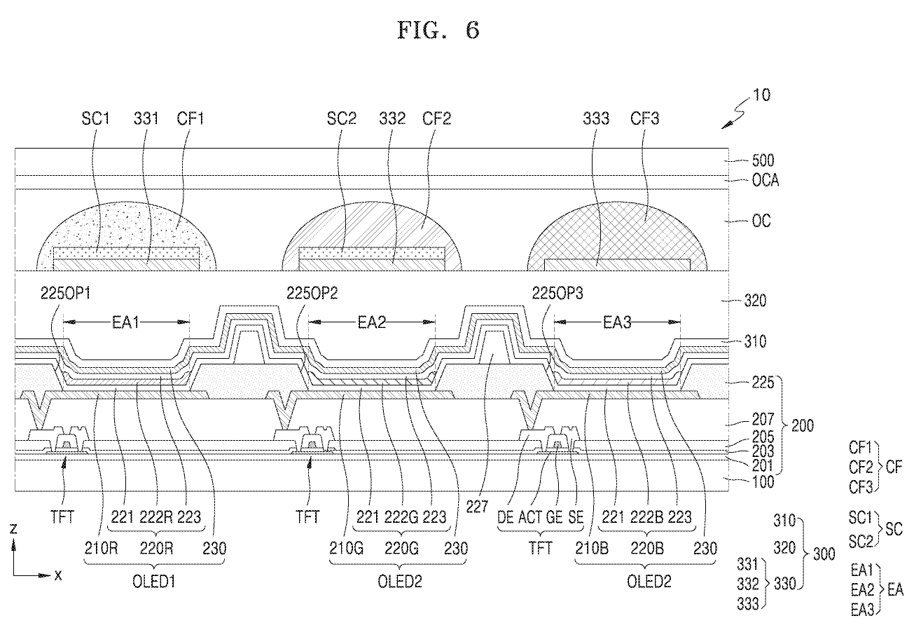

FIG. 6 is a schematic cross-sectional view of a display device 10 according to an embodiment. FIG. 6 may represent structures in the display area DA of the display device 10. FIG. 6 may be a view of a light emission area and a non-emission area within the display area DA.

Referring to FIG. 6, the display device 10 may include a substrate 100, a display layer 200, an encapsulation layer 300, an anti-reflection layer 400, an adhesive layer OCA, and a cover window 500.

The display device 10 may include a plurality of pixels disposed in a display area (see DA of FIG. 3). Each of the pixels P may be configured to emit red light, green light, or blue light. The pixels P may include pixels P configured to emit different colors from each other, for example, a first color pixel, a second color pixel and a third color pixel. The first color pixel, the second color pixel and the third color pixel may each be provided in plurality. In an embodiment, the first color pixel may be a red pixel configured to emit red light, the second color pixel may be a green pixel configured to emit green light, and the third color pixel may be a blue pixel configured to emit blue light.

The display layer 200 may be disposed on the substrate 100. The display layer 200 may include a pixel circuit layer and a light-emitting element layer. The pixel circuit layer may include thin-film transistors TFT and may include insulating layers, such as a buffer layer 201, a gate insulating layer 203, an interlayer insulating layer 205, and a planarization layer 207.

The buffer layer 201 may be disposed on the substrate 100. The buffer layer 201 may reduce or prevent infiltration of foreign material, moisture, or ambient air from below the substrate 100, and may provide a flat surface on the substrate 100. The buffer layer 201 may include an inorganic material, such as an oxide or a nitride, an organic material, or an organic/inorganic composite material and may have a single-layer or multilayer structure including an inorganic material and an organic material. A barrier layer (not shown) which prevents infiltration of ambient air may be further included between the substrate 100 and the buffer layer 201. For example, the buffer layer 201 may include silicon oxide or silicon nitride.

The thin-film transistor TFT may be disposed on the buffer layer 201. The thin-film transistor TFT may include a semiconductor layer ACT, a gate electrode GE, a source electrode SE, and a drain electrode DE. The thin-film transistor TFT may be connected to an organic light-emitting element and configured to drive the organic light-emitting diode OLED.

The semiconductor layer ACT may be disposed on the buffer layer 201. The semiconductor layer ACT may include polysilicon or amorphous silicon. Alternatively, the semiconductor layer ACT may include an oxide of at least one selected from indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer ACT may include a channel region, and a source region and a drain region doped with impurities.

The gate electrode GE, the source electrode SE, and the drain electrode DE may each include various conductive materials. In an embodiment, the gate electrode GE may include at least one of molybdenum (Mo), aluminum (Al), copper (Cu) and titanium (Ti). For example, the gate electrode GE may be a single molybdenum (Mo) layer, or may have a three-layer structure including a molybdenum (Mo) layer, an aluminum (Al) layer, and a molybdenum (Mo) layer. In an embodiment, the source electrode SE and the drain electrode DE may include at least one material selected from copper (Cu), titanium (Ti), and aluminum (Al). For example, the source electrode SE and the drain electrode DE may each have a three-layer structure including a titanium (Ti) layer, an aluminum (Al) layer, and a titanium (Ti) layer.

To ensure insulation between the semiconductor layer ACT and the gate electrode GE, the gate insulating layer 203 may be disposed between the semiconductor layer ACT and the gate electrode GE. The interlayer insulating layer 205 may be disposed on the gate electrode GE, and the source electrode SE and the drain electrode DE may be disposed on the interlayer insulating layer 205.

The gate insulating layer 203 and the interlayer insulating layer 205 may each include an inorganic material, such as silicon oxide, silicon nitride, and/or silicon oxynitride. The gate insulating layer 203 and the interlayer insulating layer 205 may each be formed by, for example, chemical vapor deposition (CVD) or atomic layer deposition (ALD).

The planarization layer 207 may be disposed on the thin-film transistor TFT. To provide a flat upper surface, after the planarization layer 207 is formed, chemical mechanical polishing may be performed on the upper surface of the planarization layer 207. The planarization layer 207 may include general-purpose polymer (e.g., photosensitive polyimide, polyimide, polystyrene (PS), polycarbonate (PC), benzocyclobutene (BCB), hexamethyldisiloxane (HMDSO), polymethylmethacrylate (PMMA), etc.), polymer derivatives having a phenol group, acrylic-based polymer, imide-based polymer, aryl ether-based polymer, amide-based polymer, fluorine-based polymer, p-xylene-based polymer, or vinyl alcohol-based polymer.

In FIG. 6, the planarization layer 207 is illustrated as a single layer, but in some embodiments, the planarization layer 207 may be a multilayer. Pixel electrodes 210R, 210G, and 210B of first to third organic light-emitting diodes OLED1, OLED2, and OLED3 may be electrically respectively connected to the thin-film transistors TFT through contact holes of the planarization layer 207, respectively.

The light-emitting element layer within the display layer 200 may be disposed on the pixel circuit layer. In an embodiment, the light-emitting element layer may include the first to third organic light-emitting diodes OLED1, OLED2, and OLED3, a bank layer 225, and spacers 227.

The first to third organic light-emitting diodes OLED1, OLED2, and OLED3 may be disposed on the pixel circuit layer. The first organic light-emitting diode OLED1 may include a stacked structure of a first pixel electrode 210R, an intermediate layer 220R, and an opposite electrode 230, the intermediate layer 220R including a first common layer 221, an emission layer 222R, and a second common layer 223. The second organic light-emitting diode OLED2 may include a second pixel electrode 210G, an intermediate layer 220G, and an opposite electrode 230, the intermediate layer 220G including a first common layer 221, an emission layer 222G, and second common layer 223. The third organic light-emitting diode OLED3 may include a third pixel electrode 210B, an intermediate layer 220B, and an opposite electrode 230, the intermediate layer 220B including a first common layer 221, an emission layer 222B, and a second common layer 223.

The first, second, and third pixel electrodes 210R, 210G, and 210B in a pixel electrode layer may be disposed on the planarization layer 207. The first, second, and third pixel electrodes 210R, 210G, and 210B may be spaced apart from each other in a direction along the display layer 200.

The first, second, and third pixel electrodes 210R, 210G, and 210B may each be a reflective electrode. The first, second, and third pixel electrodes 210R, 210G, and 210B may include a reflective layer and a transparent or semitransparent electrode layer which is disposed on the reflective layer. The reflective layer may include silver (Ag), magnesium (Mg), aluminum (Al), platinum (Pt), palladium (Pd), gold (Au), nickel (Ni), neodymium (Nd), iridium (Ir), chromium (Cr), or any combination thereof. The transparent or semitransparent electrode layer may include at least one material selected from indium tin oxide (ITO), indium zinc oxide (IZO), zinc oxide (ZnO), indium oxide (In₂O₃), indium gallium oxide (IGO), and aluminum zinc oxide (AZO).

The bank layer 225 may be disposed on the first, second, and third pixel electrodes 210R, 210G, and 210B. A solid portion (e.g., material portion) of the bank layer 225 may have (or define) first to third lower openings 225OP1, 225OP2, and 2225OP3 respectively overlapping the first, second, and third pixel electrodes 210R, 210G, and 210B and exposing the central portions of the first, second, and third pixel electrodes 210R, 210G, and 210B. A bank (e.g., the solid portion) of the bank layer 225 may cover the edges of the first, second, and third pixel electrodes 210R, 210G, and 210B and may prevent an electric arc or the like from occurring on the edges of the first, second, and third pixel electrodes 210R, 210G, and 210B. Prevention of the arc may be achieved by the bank overlapping outer edges of the various pixel electrode to increase the distance between the edge of each of the first, second, and third pixel electrodes 210R, 210G, and 210B and the opposite electrode 230.

The first to third lower openings 225OP1, 225OP2, and 225OP3 as bank openings of the bank layer 225 may respectively define first to third emission areas EA1, EA2, and EA3 of the first to third organic light-emitting diodes OLED1, OLED2, and OLED3 included in each pixel P. As illustrated in FIG. 6, the bank layer 225 may include the first lower opening 225OP1 defining the first emission area EA1 of the first organic light-emitting diode OLED1 of the first color pixel. In addition, the bank layer 225 may include the second lower opening 225OP2 defining the second emission area EA2 of the second organic light-emitting diode OLED2 of the second color pixel, and may include the third lower opening 225OP3 defining the third light-emitting area EA3 of the third organic light-emitting diode OLED3 of the third color pixel.

The material portion of the bank layer 225 may include an organic insulating material. Alternatively, the material portion of the bank layer 225 may include an inorganic insulating material, such as silicon nitride or silicon oxide. In some embodiments, the bank layer 225 may include an organic insulating material and an inorganic insulating material.

In an embodiment, the material portion of the bank layer 225 may include a light-blocking material. For example, the light-blocking material of the bank layer 225 may be black. The light-blocking material may include carbon black, carbon nanotubes, a resin or paste including black dye, metal particles (e.g., nickel, aluminum, molybdenum, and any alloy thereof), metal oxide particles, or metal nitride particles. When the bank layer 225 includes a light-blocking material, the reflection of external light due to the metal structures below the bank layer 225 may be reduced.

The spacer 227 may be disposed on the bank of the bank layer 225. The spacer 227 may include an organic insulating material, such as polyimide. Alternatively, the spacer 227 may include an inorganic insulating material, such as silicon nitride or silicon oxide, or may include an organic insulating material and an inorganic insulating material. In an embodiment, the spacer 227 may include a material which is different than a material of the bank of the bank layer 225 including the light-blocking material described above, and may be formed in a separate process.

In an embodiment, the spacer 227 may include the same material as the material of the bank of the bank layer 225. In this case, the bank layer 225 and the spacer 227 may be formed together in a mask process using a half-tone mask or the like. The bank and the spacer 227 may provide a continuous or single body.

The bank of the bank layer 225 and the spacer 227 may overlap a non-emission area which is adjacent to the emission area EA. The bank openings may define a boundary between the non-emission area and the emission area EA, without being limited thereto.

The intermediate layer may be disposed on the first, second, and third pixel electrodes 210R, 210G, and 210B and the bank layer 225. As described above, the intermediate layer may include the first common layer 221, the emission layer, and the second common layer 223.

The emission layers 222R, 222G, and 222B of the emission layer may be respectively disposed inside the first to third lower openings 225OP1, 225OP2, and 225OP3 of the bank layer 225. The emission layers 222R, 222G, and 222B may each be an organic material including a fluorescent or phosphorescent material capable of emitting red light, green light, or blue light. The organic material described above may include a low molecular weight organic material or a high molecular weight organic material. The emission layers 222R, 222G, and 222B may be patterns spaced apart from each other along the display layer 200.

The first common layer 221 and the second common layer 223 may be respectively disposed below and above the emission layer. For example, the first common layer 221 may include a hole transport layer (HTL), or may include an HTL and a hole injection layer (HIL). For example, the second common layer 223 may include an electron transport layer (ETL), or may include an ETL and an electron injection layer (EIL). In an embodiment, the second common layer 223 may not be provided.

While the emission layers are respectively disposed for each pixel to correspond to the first to third lower openings 225OP1, 225OP2, and 225OP3 of the bank layer 225, the first common layer 221 and the second common layer 223 may be integrally formed to completely cover the substrate 100. In other words, the first common layer 221 and the second common layer 223 may be a continuous layer integrally formed to completely cover the display area DA of the substrate 100.

The opposite electrode 230 may be a cathode which is an electron injection electrode. The opposite electrode 230 may include a conductive material having a low work function. For example, the opposite electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 230 may further include a layer including ITO, IZO, ZnO, or In₂O₃ on the (semi)transparent layer including the material described above.

In an embodiment, a capping layer (not shown) may be further disposed on the display layer 200 and below the encapsulation layer 300. The capping layer may be disposed on the first to third organic light-emitting diodes OLED1, OLED2, and OLED3. In an embodiment, the capping layer may improve the light emission efficiency of the first to third organic light-emitting diodes OLED1, OLED2, and OLED3 by the principle of constructive interference.

The capping layer may be an organic capping layer including an organic material, an inorganic capping layer including an inorganic material, or a composite capping layer including an organic material and an inorganic material. For example, the capping layer may include a carbocyclic compound, a heterocyclic compound, an amine group-containing compound, porphine derivatives, phthalocyanine derivatives, naphthalocyanine derivatives, an alkali metal complex, an alkaline earth metal complex, or any combination thereof. The carbocyclic compound, the heterocyclic compound, and the amine group-containing compound may be optionally substituted with a substituent including O, N, S, Se, Si, F, Cl, Br, I, or any combination thereof. Hereinafter, a case where the capping layer is omitted is mainly described.

An encapsulation layer 300 may be disposed on the opposite electrode 230. The encapsulation layer 300 may include at least one inorganic encapsulation layer and at least one organic encapsulation layer. For example, as illustrated in FIG. 6, the encapsulation layer 300 may include a first inorganic encapsulation layer 310, an organic encapsulation layer 320, and a second inorganic encapsulation layer 330, which are sequentially stacked in this stated order.

The first inorganic encapsulation layer 310 and the second inorganic encapsulation layer 330 may each include an inorganic insulating material, such as silicon oxide, silicon nitride, silicon oxynitride, aluminum oxide, titanium oxide, tantalum oxide, hafnium oxide, or zinc oxide. The first inorganic encapsulation layer 310 and the second inorganic encapsulation layer 330 may each have a single-layer or multilayer structure including the inorganic insulating material described above.

The organic encapsulation layer 320 may relieve internal stress of the first inorganic encapsulation layer 310 and/or the second inorganic encapsulation layer 330. The organic encapsulation layer 320 may include a monomer or a polymer. For example, the organic encapsulation layer 320 may include ethylene, propylene, or styrene, or may include polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate, polyacrylic acid, etc.), or any combination thereof.

In an embodiment, the first inorganic encapsulation layer 310 may be disposed on the opposite electrode 230. The first inorganic encapsulation layer 310 may be disposed to cover the entire surface of the substrate 100. The organic encapsulation layer 320 may be disposed on the first inorganic encapsulation layer 310.

The second inorganic encapsulation layer 330 may be disposed on the organic encapsulation layer 320. At this time, the second inorganic encapsulation layer 330 may be patterned to include an encapsulation pattern provided in plural in a direction along the organic encapsulation layer 320. In an embodiment, in a plan view, the second inorganic encapsulation layer 330 may be disposed to overlap the emission areas EA. For example, the second inorganic encapsulation layer 330 may include a first encapsulation member 331 disposed on the organic encapsulation layer 320 to overlap the first emission area EA1, a second encapsulation member 332 disposed on the organic encapsulation layer 320 to overlap the second emission area EA2, and a third encapsulation member 333 disposed on the organic encapsulation layer 320 to overlap the third emission area EA3.

The second inorganic encapsulation layer 330 may be disposed in a disconnected manner by patterns spaced apart from each other. Accordingly, the first encapsulation member 331, the second encapsulation member 332, and the third encapsulation member 333 may be spaced apart from each other with a gap therebetween. In addition, in a plan view, the first encapsulation member 331, the second encapsulation member 332, and the third encapsulation member 333 may overlap the first pixel electrode 210R, the second pixel electrode 210G, and the third pixel electrode 210B, respectively. The patterns of the second inorganic encapsulation layer 330 may be discrete patterns in the plan view (e.g., along the XY plane), without being limited thereto.

In an embodiment, openings defined in the second inorganic encapsulation layer 330 by the encapsulation members thereof spaced apart from each other may expose a portion of the organic encapsulation layer 320 to outside the second inorganic encapsulation layer 330. Here, openings in the color filter layer (e.g., the color filter CF) are defined to be empty, where the exposed upper surfaces of the organic encapsulation layer 200 are exposed to the color filter openings. The second inorganic encapsulation layer 330 may be disposed on the upper surface of the organic encapsulation layer 320 corresponding to the emission areas EA, and a remaining portion of the upper surface of the organic encapsulation layer 320 may be exposed to outside the second inorganic encapsulation layer 330. The exposed portion of the organic encapsulation layer 320 may be coated to have hydrophobicity, as described below. For example, the exposed portion of the organic encapsulation layer 320 may be surface-treated with carbon tetrafluoride (CF₄). Accordingly, the exposed portion of the organic encapsulation layer 320 may have hydrophobicity.

The anti-reflection layer 400 may be disposed on the encapsulation layer 300. In an embodiment, the anti-reflection layer 400 may include a scattering layer SC, a plurality of color filters CF, and an overcoat layer OC.

The scattering layer SC may be disposed on the second inorganic encapsulation layer 330. The scattering layer SC may increase color reproducibility and reduce color distortion by scattering light of a specific wavelength band from light emitted from the emission area EA. At this time, the scattering layer SC may be patterned to include solid portions as scattering patterns with openings therebetween.

In an embodiment, in a plan view, a solid portion (e.g., a material portion) of the scattering layer SC may be disposed to overlap the first emission area EA1 and the second emission area EA2. In a plan view, the scattering layer SC may not be disposed on the third emission area EA3. That is, the scattering layer SC may not be disposed in the third emission area EA3, for example, the area (e.g., the planar area) form which blue light is emitted. For example, the scattering layer SC may include a first scattering portion SC1 disposed on the first encapsulation member 331 to overlap the first emission area EA1 and a second scattering portion SC2 disposed on the second encapsulation member 332 to overlap the second emission area EA2. At this time, the first scattering portion SC1 may overlap the first encapsulation member 331, and the second scattering portion SC2 may overlap the second encapsulation member 332. The scattering layer SC may be disposed in a disconnected manner, and accordingly, the first scattering portion SC1 and the second scattering portion SC2 may be spaced apart from each other by a gap or opening in the scattering layer SC. In addition, in a plan view, the first scattering portion SC1 and the second scattering portion SC2 may overlap the first pixel electrode 210R and the second pixel electrode 210G, respectively.

In an embodiment, openings defined in the scattering layer SC may expose a portion of the organic encapsulation layer 320 together with the second inorganic encapsulation layer 330, to outside the scattering layer SC. The second inorganic encapsulation layer 330 may be disposed on the upper surface of the organic encapsulation layer 320 corresponding to the emission areas EA, and the remaining portion of the organic encapsulation layer 320 may be exposed.

The color filters CF may be disposed on the scattering layer SC. The color filters CF may include first to third color filters CF1, CF2, and CF3 as color filter patterns of different colors corresponding to the first to third organic light-emitting diodes OLED1, OLED2, and OLED3, respectively. In a plan view, the color filters CF may be disposed to overlap the emission areas EA. The first to third color filters CF1, CF2, and CF3 may have colors corresponding to pieces of light emitted from the first to third emission areas EA1, EA2, and EA3. For example, when red light is emitted from the first emission area EA1, the first color filter CF1 may be a red color filter, when green light is emitted from the second emission area EA2, the second color filter CF2 may be a green color filter, and when blue light is emitted from the third emission area EA3, the third color filter CF3 may be a blue color filter.

In an embodiment, each of the color filters CF may cover the scattering layer SC and/or the second inorganic encapsulation layer 330. The first color filter CF1 may cover the first scattering portion SC1 and the first encapsulation member 331 below the first scattering portion SC1. In a plan view, the first color filter CF1 may cover the first scattering portion SC1 and the first encapsulation member 331 so that the first scattering portion SC1 and the first encapsulation member 331 are disposed within the periphery of the first color filter CF1. In an embodiment, the first color filter CF1 may have a convex hemispherical shape.

The second color filter CF2 may cover the second scattering portion SC2 and the second encapsulation member 332 below the second scattering portion SC2. In a plan view, the second color filter CF2 may cover the second scattering portion SC2 and the second encapsulation member 332 so that the second scattering portion SC2 and the second encapsulation member 332 are disposed within the periphery of the second color filter CF2. In an embodiment, the second color filter CF2 may have a convex hemispherical shape.

The third color filter CF3 may cover the third encapsulation member 333. In a plan view, the third color filter CF3 may cover the third encapsulation member 333 so that the third encapsulation member 333 is disposed within the periphery of the third color filter CF3. In an embodiment, the third color filter CF3 may have a convex hemispherical shape.

While FIG. 6 shows one direction along the XY plane, it will be understood that cross-sectional shapes of the elements in FIG. 6 may extend in any of a number of planar directions along the XY plane. For example, where each of the encapsulation member, the scattering member and the color filter has a planar shape (e.g., in a plan view along the Z-axis), such planar shape may define a periphery. As described above, a periphery of the encapsulation member and/or the scattering member may be within a periphery of the color filter. In detail, the color filter may extend further than a side surface (or sidewall) of the encapsulation member and/or the scattering member such that the encapsulation member and/or the scattering member is within the periphery of the color filter.

In an embodiment, the first color filter CF1, the second color filter CF2, and the third color filter CF3 may be spaced apart from each other with a gap or color filter opening therebetween. The first color filter CF1, the second color filter CF2, and the third color filter CF3 may be formed by jetting ink. As described above, since the exposed surface of the organic encapsulation layer 320 which comes into contact with the color filter CF is coated hydrophobically, the color filter CF may have a convex hemispherical shape and may be aggregated within the emission areas EA. Accordingly, the color filter CF may be formed by ink jetting alone without requiring a separate layer to define openings in which a color filter ink is accommodated. That is, in a method of providing a light control layer like the anti-reflection layer 400, a process of forming a separate layer to accommodate the color filter CF, for example, a process of depositing a separate layer, performing photolithography, and then performing etching, may be omitted, and thus, process efficiency may be improved and costs may be reduced. In addition, LvA of the color filter CF may be improved by forming the color filter CF in a convex hemispherical shape, i.e., in a dome shape. LvA may refer to a ratio of side light output efficiency to top light output efficiency.

A light control pattern may be defined by various patterns of the second inorganic encapsulation layer 330, the scattering layer SC and the color filter CF which are in respectively on the upper surface of the organic encapsulation layer 320. The patterns may provide thickness portions of the light control pattern. In an embodiment, a first light control pattern may have the first encapsulation member 331 as a first thickness portion, the first scattering portion SC1 as a second thickness portion and the first color filter CF1 as a third thickness portion. Following the same reasoning, at the third emission area EA3, there may be two thickness portions in total.

The overcoat layer OC may be disposed on the color filters CF. The overcoat layer OC may be disposed to cover the color filters CF. The overcoat layer OC may cover the color filters CF and may fill gaps between the color filters CF to come into contact with the organic encapsulation layer 320. In addition, the upper surface of the overcoat layer OC may be flat, and thus, the upper surface of the anti-reflection layer 400 may be planarized. In an embodiment, the overcoat layer OC may be a colorless, light-transmitting layer which does not have a color in a visible light band. The overcoat layer OC may include a colorless, light-transmitting organic material, such as acrylic-based resin.

In an embodiment, the refractive index of the color filter CF may be less than the refractive index of the overcoat layer OC. For example, the refractive index of the color filter CF may be about 1.5, and the refractive index of the overcoat layer OC may be about 1.65. The color filter CF and the overcoat layer OC having the refractive indices described above may implement the effect of a micro lens array.

The cover window 500 may be disposed on the overcoat layer OC with the adhesive layer OCA therebetween.

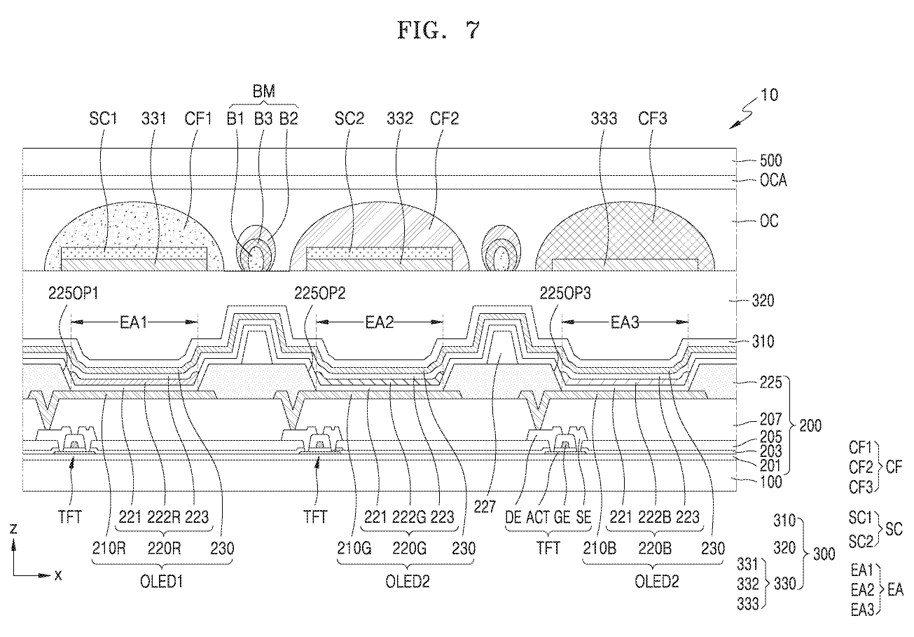

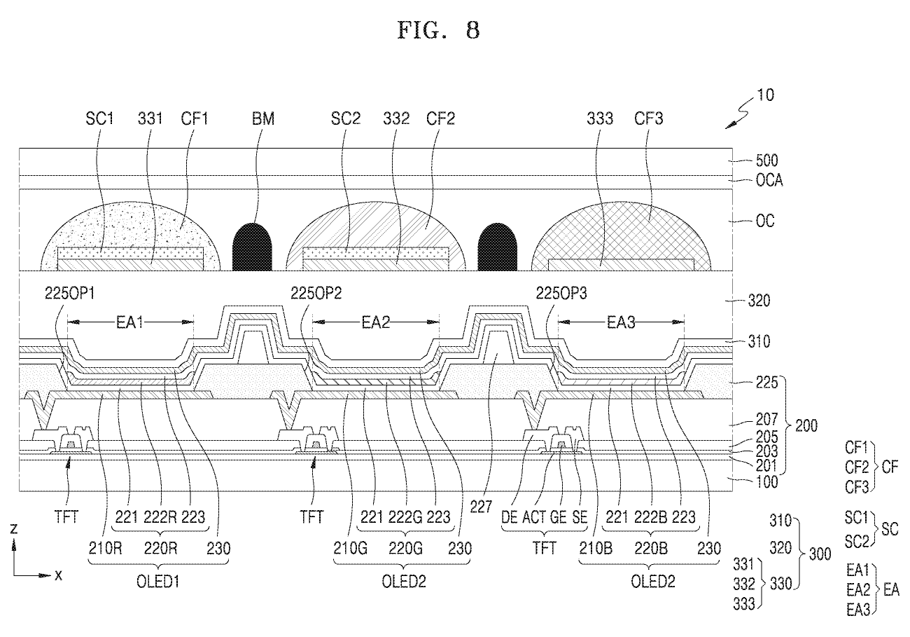

FIGS. 7 and 8 are schematic cross-sectional views of a display device 10 according to an embodiment. Since the display device 10 according to the present embodiment is similar to the display device described above, only the differences are mainly described.

Referring to FIG. 7, the anti-reflection layer 400 may further include a light-blocking portion BM. The light-blocking portion BM may reduce external light reflection and prevent light leakage at a non-emission area adjacent to the emission area EA. In an embodiment, the light-blocking portion BM may be disposed between the color filters CF spaced apart from each other. At this time, the light-blocking portion BM may be spaced apart from the respective color filters CF by a certain distance in a direction along the organic encapsulation layer 320. For example, the light-blocking portion BM may be disposed between the first color filter CF1 and the second color filter CF2 and spaced apart from the first color filter CF1 and the second color filter CF2 by a certain distance, and may be disposed between the second color filter CF2 and the third color filter CF3 and spaced apart from the second color filter CF2 and the third color filter CF3 by a certain distance. In an embodiment, in a plan view, the light-blocking portion BM may extend along the periphery of each of the color filters CF in the plan view. In this case, it will be understood that the light-blocking portion BM may be spaced from the periphery as an outer edge of the color filter CF.

In an embodiment, the light-blocking portion BM may include a first portion B1 as a first thickness portion, a second portion B2 as a second thickness portion, and a third portion B3 as a third thickness portion. In an embodiment, the first portion B1 may include the same material as the material of the first color filter CF1. The second portion B2 may include the same material as the material of the second color filter CF2. The third portion B3 may include the same material as the material of the third color filter CF3. As including the same material, portions may be considered to be in a same layer. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

In an embodiment, the light-blocking portion BM may have a structure in which the first portion B1, the second portion B2, and the third portion B3 are stacked, such as in order from the organic encapsulation layer 320. For example, the first portion B1 may be disposed on the organic encapsulation layer 320, the third portion B3 may be disposed to surround the first portion B1, and the third portion B3 may be disposed to surround the second portion B2. As another example, the third portion B3 may be disposed on the organic encapsulation layer 320, the first portion B1 may be disposed to surround the third portion B3, and the second portion B2 may be disposed to surround the first portion B1. In other words, the uppermost layer of a respective light-blocking pattern (e.g., light-blocking portion BM) may be the second portion B2 including the same material as the material of the green color filter, and the stacking order of the first portion B1 and the third portion B3 may be changed. In an embodiment, the light-blocking portion BM may include a first thickness portion and a second thickness portion which is on the first thickness portion, the first color filter CF1 and the first thickness portion may be respective portions of a same material layer, and the second color filter CF2 and the the second thickness portion may be respective portions of a same material layer. Here, the second thickness portion surrounds the first thickness portion.

The first portion B1, the second portion B2, and the third portion B3 may be formed together in a respective ink jetting process of the color filter CF. Accordingly, process efficiency may be improved and costs may be reduced since a separate additional process for forming the light-blocking portion BM is not required.

Referring to FIG. 8, in an embodiment, the light-blocking portion BM may include a black material. For example, the light-blocking portion BM may include at least one of carbon black, carbon nanotubes, and a resin including a black dye. The light-blocking portion BM may be formed by jetting a black material through an ink jetting process.

In one or more embodiments, a display device 10 includes a bank layer 225 in which openings (like 225OP1 and 225OP2) are defined respectively defining a first emission area EA1 and a second emission area EA2, a first light-emitting element and a second light-emitting element (like OLED1 and OLED2) in the first emission area EA1 and in the second emission area EA2, respectively, an organic encapsulation layer 320 on the bank layer 225, a color filter layer on the organic encapsulation layer 320, the color filter layer including a first color filter CF1 overlapping the first light-emitting element and a second color filter CF2 overlapping the second light-emitting element, the first color filter CF1 spaced apart from the second color filter CF2 with a gap therebetween, and an overcoat layer OC covering the first color filter CF1 and the second color filter CF2 and extended into the gap between the first color filter CF1 and the second color filter CF2.

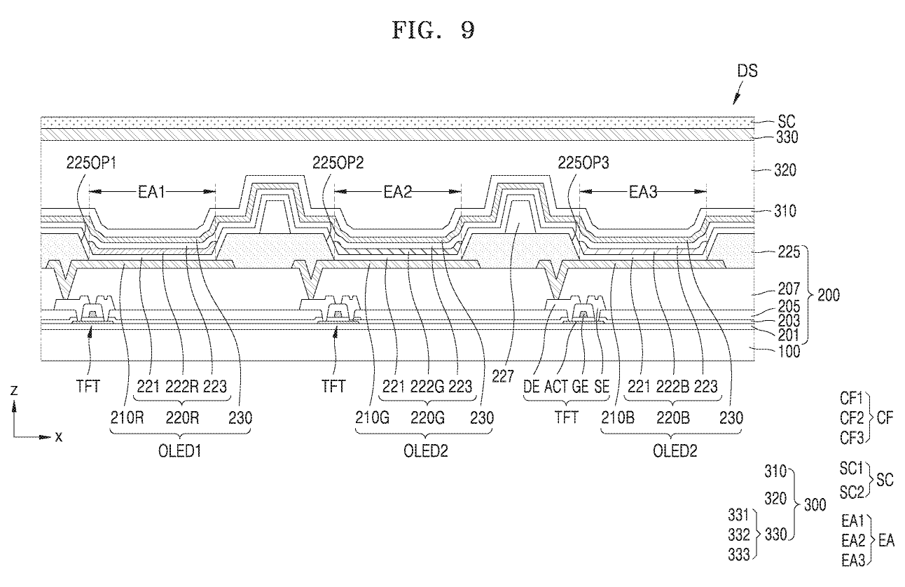

FIGS. 9 to 11 schematically illustrate a method of manufacturing (or providing) a display device 10, according to an embodiment. The method of manufacturing a display device 10, according to an embodiment, may be used to manufacture the display device 10 described above, but the disclosure is not necessarily limited thereto.

Referring to FIG. 9, a display substrate DS may be disposed. The display substrate DS may refer to a portion of a final form of a display device 10 which is being manufactured or provided by the method. For example, the display substrate DS may refer to a state in which a display layer 200, an encapsulation layer 300, etc. are stacked on a substrate 100.

In the display substrate DS, a second inorganic encapsulation layer 330 in a preliminary form may be disposed on an organic encapsulation layer 320. In addition, a scattering layer SC in a preliminary form may be disposed on the second inorganic encapsulation layer 330. In an embodiment, the second inorganic encapsulation layer 330 and the scattering layer SC may be formed by deposition on the organic encapsulation layer 320 over the entire surface of the display substrate DS.

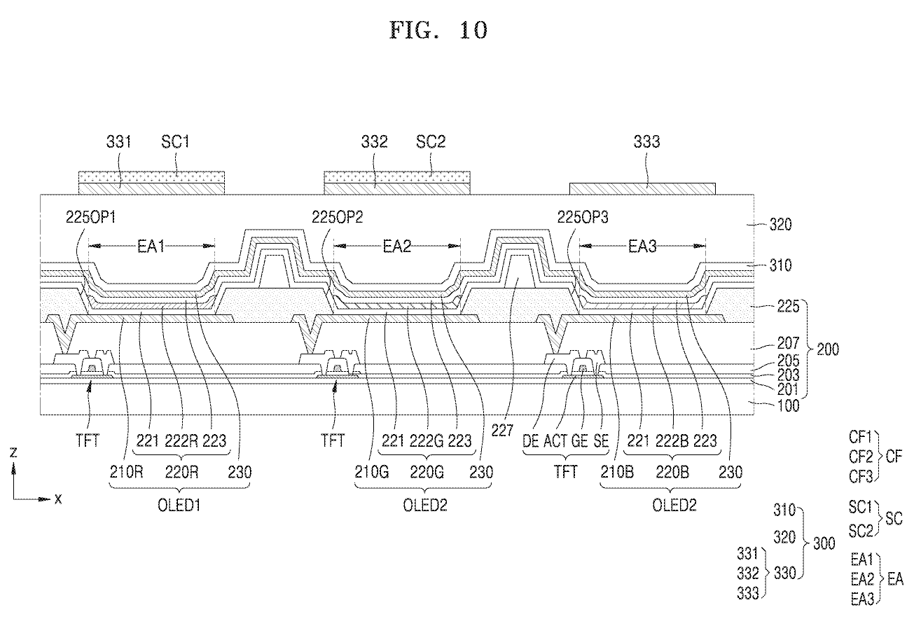

Referring to FIG. 10, preliminary layers from which the second inorganic encapsulation layer 330 and the scattering layer SC are respectively formed, may be patterned. In an embodiment, the second inorganic encapsulation layer 330 and the scattering layer SC may be patterned through photolithography and etching processes. At this time, a half-tone mask may be used in the photolithography process. Accordingly, the second inorganic encapsulation layer 330 and the scattering layer SC may be patterned in a portion overlapping the emission area EA, on the organic encapsulation layer 320. For example, from a preliminary inorganic encapsulation layer, a first encapsulation member 331 and a first scattering portion SC1 may be formed to overlap a first emission area EA1, and a second encapsulation member 332 and a second scattering portion SC2 may be formed to overlap a second emission area EA2. In addition, a third encapsulation member 333 may be formed to overlap a third emission area EA3. It will be understood that the use of the half-tone mask may prevent the scattering layer SC from being formed only in the third emission area EA3.

In an embodiment, the upper surface of the display substrate DS may be coated to have hydrophobicity. In an embodiment, after the second inorganic encapsulation layer 330 and the scattering layer SC are patterned, the upper surface of the display substrate DS, for example, the upper surface of the scattering layer SC and the upper surface of the organic encapsulation layer 320 at the exposed portion thereof, may be surface-treated with carbon tetrafluoride (CF₄). Carbon tetrafluoride (CF₄) may react with the organic encapsulation layer 320 to make the exposed upper surface of the organic encapsulation layer 320 hydrophobic. Here, an upper surface of the display substrate DS may be defined by upper surfaces of the encapsulation members together with the exposed upper surfaces of the organic encapsulation layer 320. However, only the exposed upper surfaces of the organic encapsulation layer 320 may have hydrophobicity owing to the reaction with the surface-treatment of the carbon tetrafluoride (CF₄).

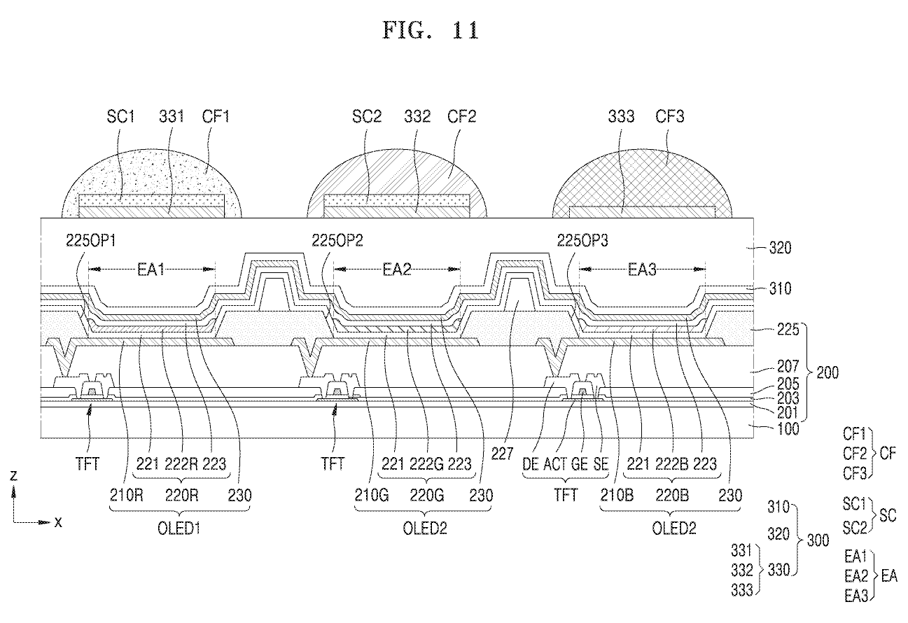

Referring to FIG. 11, a color filter CF may be formed by jetting ink to cover the second inorganic encapsulation layer 330 and the scattering layer SC. At this time, since the exposed upper surface of the organic encapsulation layer 320 is hydrophobic while the upper surface at the encapsulation members is not subject to the reaction with the carbon tetrafluoride (CF₄), the jetted ink may be aggregated to have a convex hemispherical dome shape.

In addition, in an embodiment, the ink material may be jetted to form a light-blocking portion BM, as illustrated in FIG. 7. In an embodiment, inks including the same material as the material of the color filters CF may be sequentially jetted to form the light-blocking portion BM. At this time, as described above, the light-blocking portion BM may be disposed extended along the periphery of each of the color filters CF in the plan view and may be spaced apart from the periphery of the color filters CF in a direction along the organic encapsulation layer 320. In other words, the light-blocking portion BM may be disposed between the color filters CF and spaced apart from each other by a certain distance.

Referring back to FIGS. 6, 7 and 8, an overcoat layer OC may be disposed to cover the color filters CF and/or the light-blocking portion BM. In addition, a cover window 500 may be disposed on the overcoat layer OC with an adhesive layer OCA therebetween, to finally form the display device 10.

In the method of manufacturing (or providing) a display device 10, according to an embodiment, a separate layer having openings in which a material forming a color filter is accommodated, is not required. Instead, the color filter may be formed to correspond to an emission area only by ink jetting ink material. That is, a process of forming a separate layer and openings therein to accommodate a color filter material, for example, a process of depositing a separate layer, performing photolithography, and then performing etching, may be omitted. Thus, process efficiency may be improved and costs may be reduced.

According to embodiments, process efficiency may be improved since a separate layer and openings therein to accommodate a color filter material is not required.

In an embodiment, the method may include providing a bank layer 225 defining an opening corresponding to an emission area EA of the display device 10, providing a light-emitting element in the opening of the bank layer 225, providing an organic encapsulation layer 320 and an inorganic encapsulation layer 330 of an encapsulation layer, on the light-emitting element, providing a scattering layer SC on the inorganic encapsulation layer 300, patterning the inorganic encapsulation layer 330 and the scattering layer SC to provide both an inorganic encapsulation member (like 331) and a scattering member (like SC1) in the emission area and on the organic encapsulation layer 320, and an exposed surface of the organic encapsulation layer 320 which is exposed to outside the inorganic encapsulation layer 330 and the scattering layer SC, the exposed surface being adjacent to the inorganic encapsulation member and the scattering member, and providing a color filter CF by jetting ink to cover the inorganic encapsulation member and the scattering member.

The method may further include hydrophobically treating the exposed surface of the organic encapsulation layer 320.

The jetting of the ink may provide the color filter CF having a convex hemispherical shape in a direction away from the organic encapsulation layer 320. The providing of the color filter CF may dispose the inorganic encapsulation member and the scattering member within a periphery of the color filter CF.

The method may further include providing a light-blocking portion extended along the exposed surface of the organic encapsulation layer 320 and along a periphery of the color filter CF.

In an embodiment, an electronic device 1 may include a processor, and a display device 10 configured to be controlled by the processor. The display device 10 includes a bank layer 225 in which an opening is defined corresponding to an emission area of the display device 10, a light-emitting element in the opening of the bank layer 225, an encapsulation layer on the bank layer and the light-emitting element, the encapsulation layer including an organic encapsulation layer 320 and an inorganic encapsulation layer in order from the bank layer 225, and the organic encapsulation layer 320 including an exposed surface which is adjacent to the inorganic encapsulation layer and exposed to outside the inorganic encapsulation layer, and a color filter CF overlapping the light-emitting element and contacting the organic encapsulation layer at the exposed surface of the organic encapsulation layer.

The effects of the disclosure are not limited to those described above, and other effects that are not described herein will be clearly understood from the description of the claims by those of ordinary skill in the art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a bank layer in which openings are defined respectively defining a first emission area and a second emission area;
a first light-emitting element and a second light-emitting element in the first emission area and in the second emission area, respectively;
an organic encapsulation layer on the bank layer;
a color filter layer on the organic encapsulation layer, the color filter layer including a first color filter overlapping the first light-emitting element and a second color filter overlapping the second light-emitting element, the first color filter spaced apart from the second color filter with a gap therebetween; and
an overcoat layer covering the first color filter and the second color filter and extended into the gap between the first color filter and the second color filter.

2. The display device of claim 1, wherein a surface of the organic encapsulation layer is exposed to outside the color filter layer at the gap and is hydrophobic.

3. The display device of claim 1, wherein the first color filter and the second color filter each have a convex hemispherical dome shape in a direction away from the organic encapsulation layer.

4. The display device of claim 1, further comprising an encapsulation layer covering the first light-emitting element and the second light-emitting element,
wherein the encapsulation layer comprises:
the organic encapsulation layer,
an inorganic encapsulation layer between the organic encapsulation layer and the first color filter and between the organic encapsulation layer and the second color filter, and
the inorganic encapsulation layer including:
a first encapsulation member overlapping the first color filter, and
a second encapsulation member overlapping the second color filter and spaced apart from the first encapsulation member.

5. The display device of claim 4, further comprising a scattering layer between the inorganic encapsulation layer and the color filter layer,
wherein the scattering layer includes:
a first scattering portion on the first encapsulation member, and
a second scattering portion on the second encapsulation member.

6. The display device of claim 5, wherein the first encapsulation member and the first scattering portion are within a periphery of the first color filter.

7. The display device of claim 1, further comprising a light-blocking portion in the gap between the first color filter and the second color filter,
wherein the light-blocking portion is spaced apart from the first color filter and the second color filter.

8. The display device of claim 7, wherein
the light-blocking portion comprises a first thickness portion and a second thickness portion which is on the first thickness portion,
the first color filter and the first thickness portion are respective portions of a same material layer, and
the second color filter and the the second thickness portion are respective portions of a same material layer.

9. The display device of claim 8, wherein the second thickness portion surrounds the first thickness portion.

10. The display device of claim 7, wherein the light-blocking portion comprises a black material.

11. A method of providing a display device, the method comprising:
providing a bank layer defining an opening corresponding to an emission area of the display device;
providing a light-emitting element in the opening of the bank layer;
providing an organic encapsulation layer and an inorganic encapsulation layer of an encapsulation layer, on the light-emitting element;
providing a scattering layer on the inorganic encapsulation layer;
patterning the inorganic encapsulation layer and the scattering layer to provide:
an inorganic encapsulation member and a scattering member in the emission area and on the organic encapsulation layer, and
an exposed surface of the organic encapsulation layer which is exposed to outside the inorganic encapsulation layer and the scattering layer, the exposed surface being adjacent to the inorganic encapsulation member and the scattering member; and
providing a color filter by jetting ink to cover the inorganic encapsulation member and the scattering member.

12. The method of claim 11, further comprising hydrophobically treating the exposed surface of the organic encapsulation layer.

13. The method of claim 11, wherein the jetting of the ink provides the color filter having a convex hemispherical shape in a direction away from the organic encapsulation layer.

14. The method of claim 11, wherein the providing of the color filter disposes the inorganic encapsulation member and the scattering member within a periphery of the color filter.

15. The method of claim 11, further comprising providing a light-blocking portion extended along the exposed surface of the organic encapsulation layer and along a periphery of the color filter.

16. The method of claim 15, wherein the light-blocking portion is spaced apart from the periphery of the color filter.

17. The method of claim 15, wherein the light-blocking portion and the color filter are respective portions of a same material layer.

18. The method of claim 17, wherein the providing of the light-blocking portion comprises jetting ink on the organic encapsulation layer.

19. The method of claim 15, wherein the light-blocking portion comprises a black material.

20. An electronic apparatus comprising:
a processor; and
a display device configured to be controlled by the processor,
wherein the display device comprises:
a bank layer in which an opening is defined corresponding to an emission area of the display device;
a light-emitting element in the opening of the bank layer;
an encapsulation layer on the bank layer and the light-emitting element, the encapsulation layer comprising:
an organic encapsulation layer and an inorganic encapsulation layer in order from the bank layer, and
the organic encapsulation layer including an exposed surface which is adjacent to the inorganic encapsulation layer and exposed to outside the inorganic encapsulation layer; and
a color filter overlapping the light-emitting element and contacting the organic encapsulation layer at the exposed surface of the organic encapsulation layer.
